(19) United States
(12) Patent Application Publication
(10) Pub. No.: US 2013/0281583 A1
(43) Pub. Date: Oct. 24, 2013

(54) Method for Improving Polyimide Non-Adherence to Substrate and Polyimide Solution

(71) Applicants: Meina Zhu, Shenzhen (CN); Jianjun Zhao, Shenzhen (CN); Hsiangyin Shih, Shenzhen (CN)

(72) Inventors: Meina Zhu, Shenzhen (CN); Jianjun Zhao, Shenzhen (CN); Hsiangyin Shih, Shenzhen (CN)

(73) Assignee: SHENZHEN CHINA STAR OPTOELECTRONICS TECHNOLOGY CO. LTD., Shenzhen City, Guangdong (CN)

(21) Appl. No.: 13/521,048

(22) PCT Filed: May 4, 2012
(86) PCT No.: PCT/CN12/75056

§ 371 Date: Jul. 7, 2012

(30) Foreign Application Priority Data
Apr. 24, 2012 (CN) 201210123262.8

(51) Int. Cl. C08K 5/09; H01L 21/312; C08K 5/3415; C08K 5/04; B05D 5/06; B05D 3/10

(52) U.S. Cl. 524/104; 427/162; 427/385.5; 524/280; 524/300; 524/612; 438/780; 257/E21.259

(57) ABSTRACT

The present invention relates to a method for improving polyimide (PI) non-adherence to a substrate and a PI solution. The method includes the following steps: (1) providing a substrate and a PI solution, the PI solution comprising PI molecules and a solvent, the PI molecules having hydrophobic moieties; and (2) coating the PI solution on the substrate to form a PI film. The PI solution includes PI molecules and a solvent. The PI molecules have hydrophobic moieties. The solvent include N-methyl-2-pyrrolidone, γ-butyrolactone, butyl carbonate, or a mixture thereof. The PI molecules of the PI solution contain hydrophobic moieties and in coating the PI solution to a substrate, the hydrophobic moieties link with organic compounds on the substrate thereby enhancing affinity of the PI solution with surface of the substrate, improving the issue of PI non-adherence, and the heightening quality of printing the substrate.

### BACKGROUND OF THE INVENTION

1. Field of the Invention

The present invention relates to the technical field of liquid crystal displaying, and in particular to a method for improving polyimide (PI) non-adherence to a substrate and a PI solution.

2. The Related Arts

A PI (polyimide) film is a layer of uniform alignment film that is located on a surface of a TFT (Thin-Film Transistor) substrate and a CF (Color Filter) substrate for making liquid crystal molecules aligning in a predetermined pre-tilt angle thereby controlling the direction in which light can transmit so that through application of proper driving voltage, the purpose of displaying can be achieved. In an actual coating process of the PI film, the result of coating PI film is often affected by surface condition of TFT substrate and CF substrate. The PI solution is generally a hydrophilic substance, which can be easily spread in a non-uniform manner due to excessive residue of organic substance. Such a non-uniform spreading result is often referred to PI non-adherence. Due to the PI non-adherence, it is often that fractional bright spot occurs in a TFT-LCD product, affecting the quality of product. Thus, before coating of PI on a TFT substrate or a CF substrate, the substrate is commonly washed for the purposes of fine modification of the organic substance on the substrate surface thereby improving the coatability of the substrate and forming a dense and homogeneous PI film.

Heretofore, to effect fine modification of the organic substance on the substrate surface, washing with a cleaning agent, EUV (Extreme Ultraviolet), and AP (Atmospheric Pressure) plasma are used to remove the organic substance and improve surface condition of the substrate. General cleaning agents are amphiphilic surfactant and the mechanism of removing organic substance is to dissolve the organic substance in the solution of the cleaning agent. The principle of using EUV to remove organic substance from the substrate surface is to use ultraviolet light of 172 nm to break bonds of the organic substrate and form O radicals to decompose the organic substance into CO₂ and H₂O. The principle of using AP plasma to remove organic substance from the substrate surface is that a gas (generally a mixture gas of CDA and N₂), when subjected to high voltage, generates O radicals and O₃ radicals, which cause chemical reaction with the organic substance to generate CO₂ and H₂O. However, in using a cleaning agent to wash a substrate, the washed substrate must be subjected to printing in time; otherwise, with the lapse of time, the organic component contained in the atmosphere may get attached to the substrate, making the result of coating PI solution on a substrate deteriorating.

### SUMMARY OF THE INVENTION

An object of the present invention is to provide a method for improving PI non-adherence to a substrate, which uses a PI solution having PI molecules that have hydrophobic moieties to coat the substrate, whereby the hydrophobic moieties is linked with organic compounds on a surface of the substrate to thereby enhance affinity of the PI solution to the substrate surface, improve the issue of PI non-adherence, improve the result of coating, and heighten printing quality of the substrate.

Another object of the present invention is to provide a PI solution, which have PI molecules that have hydrophobic moieties that is linked with organic compounds on a surface of substrate to enhance affinity of the PI solution to the substrate surface, improve the issue of PI non-adherence, improve the result of coating, and thus heighten printing quality of the substrate.

To achieve the objects the present invention provides a method for improving polyimide (PI) non-adherence to a substrate, comprising the following steps:

(1) providing a substrate and a PI solution, the PI solution comprising PI molecules and a solvent, the PI molecules having hydrophobic moieties; and

(2) coating the PI solution on the substrate to form a PI film.

The substrate is a thin-film transistor (TFT) substrate or a color filter (CF) substrate.

The solvent comprises N-methyl-2-pyrrolidone (NMP), γ-butyrolactone (GBL), butyl carbonate (BC), or a mixture thereof.

The hydrophobic moieties are grafted on the PI molecules by polymerization reaction so as to form hydrophobic side chains of the PI molecules and in step (2), the PI molecules of the PI solution are linked to organic compounds on the substrate through the hydrophobic side chains thereof.

The hydrophobic moieties comprise alkane moieties.

The PI molecules are linked with amphiphiles that have both hydrophilic moieties and hydrophobic moieties. The hydrophobic moieties of the PI molecules are the hydrophobic moieties of the amphiphiles, which are linked to the PI molecules through the hydrophilic moieties linking to the PI molecules; in step (2), the PI molecules of PI solution are linked to organic compounds on the substrate through the hydrophobic moieties thereof.

Further, the present invention also provides a PI solution, which comprises PI molecules and a solvent. The PI molecules have hydrophobic moieties.

The solvent comprises N-methyl-2-pyrrolidone (NMP), γ-butyrolactone (GBL), butyl carbonate (BC), or a mixture thereof.

The hydrophobic moieties are grafted on the PI molecules by polymerization reaction so as to form hydrophobic side chains of the PI molecules.

The hydrophobic moieties comprise alkane moieties.

The PI molecules are linked with amphiphiles that have both hydrophilic moieties and hydrophobic moieties. The hydrophobic moieties of the PI molecules are the hydrophobic moieties of the amphiphiles, which are linked to the PI molecules through the hydrophilic moieties linking to the PI molecules.

The efficacy of the present invention is that the present invention provides a method for improving PI non-adherence to substrate and a PI solution. The PI solution comprises PI molecules that have hydrophobic moieties. Using the PI solution to coat on a substrate allows the hydrophobic moieties to link with organic compounds existing on a surface of the substrate to thereby enhance affinity of the PI solution to the substrate surface, improve the issue of PI non-adherence, improve the result of coating, and heighten printing quality of the substrate.

### DETAILED DESCRIPTION OF THE PREFERRED EMBODIMENTS

A method for improving polyimide (PI) non-adherence to a substrate according to an embodiment of the present invention comprises the following steps:

Step 1: providing a substrate and a PI solution. The PI solution comprises PI molecules and a solvent. The PI molecules have hydrophobic moieties. The substrate can be a thin-film transistor (TFT) substrate or a color filter (CF) substrate. The solvent can be N-methyl-2-pyrrolidone (NMP), γ-butyrolactone (GBL), butyl carbonate (BC), or a mixture thereof. In the instant embodiment, the hydrophobic moieties are grafted on the PI molecules of the PI solution to form hydrophobic side chains of the PI molecules. The hydrophobic moieties can be grafted on the PI molecules by polymerization reaction, such as ATRP (Atom Transfer Radical Polymerization), or grafting can be effected during synthesis of PI. The hydrophobic moieties can be alkane moieties or other hydrophobic moieties, which can be linked with organic compounds existing on a surface of the substrate.

Step 2: coating the PI solution on the substrate to form a PI film, in which the PI molecules of the PI solution are linked to organic compounds on the surface of the substrate through the hydrophobic moieties so that coating the PI solution on the substrate may provide a dense and homogenous PI film. In the instant embodiment, since the PI molecules of the PI solution have hydrophobic side chains, when the PI solution is coated on the substrate, the hydrophobic side chains serve as a medium to allow the PI molecules to link with the organic compounds on the substrate surface through the hydrophobic side chains, making the PI solution uniformly spread on the substrate to enhance the affinity of the PI solution on the substrate and improve the PI non-adherence issue. Through coating, the PI solution forms a dense and homogenous PI film on the substrate, thereby improving the quality of printing the substrate and preventing a TFT-LCD product to display fractional bright spot.

The PI solution used in the above method comprises PI molecules and a solvent. The PI molecules have hydrophobic moieties. The solvent can be N-methyl-2-pyrrolidone, γ-butyrolactone, butyl carbonate, or a mixture thereof and preferably a mixture of NMP, BC, and GBL. The hydrophobic moieties can be grafted on the PI molecules by polymerization reaction, such as ATRP (Atom Transfer Radical Polymerization), or grafting can be effected during synthesis of PI. The hydrophobic moieties can be alkane moieties or other hydrophobic moieties, which can be linked with organic compounds existing on a surface of the substrate.

A method for improving PI non-adherence to a substrate according to another embodiment of the present invention comprises the following steps:

Step 1: providing a substrate and a PI solution. The PI solution comprises PI molecules and a solvent. The PI molecules have hydrophobic moieties. The substrate can be a TFT substrate or a CF substrate. The solvent can be realized with the known techniques, such as N-methyl-2-pyrrolidone (NMP), γ-butyrolactone (GBL), butyl carbonate (BC), or a mixture thereof. In the instant embodiment, the PI molecules are linked with amphiphiles that have both hydrophilic moieties and hydrophobic moieties. The hydrophobic moieties of the PI molecules are the hydrophobic moieties of the amphiphiles, which are linked to the PI molecules through the hydrophilic moieties linking to the PI molecules. The amphiphiles can be any known molecule that contains both hydrophilic moieties and hydrophobic moieties of which the hydrophilic moieties can be linked with the PI molecules and the hydrophobic moieties can be linked with organic compound, especially the organic compounds existing on a surface of a substrate (such as TFT substrate or CF substrate).

Step 2: coating the PI solution on the substrate to form a PI film, in which the PI molecules of the PI solution are linked to organic compounds on the surface of the substrate through the hydrophobic moieties so that coating the PI solution on the substrate may provide a dense and homogenous PI film. In the instant embodiment, the amphiphiles serve as a medium to allow the PI molecules to link with the organic compounds on the substrate surface, namely the amphiphiles are linked to the PI molecules through the hydrophilic moieties linking to the PI molecules and the hydrophobic moieties are linked with the organic compounds on the substrate surface, making the PI solution uniformly spread on the substrate to enhance the affinity of the PI solution on the substrate and improve the PI non-adherence issue. Through coating, the PI solution forms a dense and homogenous PI film on the substrate, thereby improving the quality of printing the substrate and preventing a TFT-LCD product to display fractional bright spot.

Further, linking the amphiphiles to the PI solution can be effected by adding an amphiphilic solvent to the PI solution. The amphiphiles are the amphiphilic solvent molecules of the amphiphilic solvent. The amphiphilic solvent is added to the PI solution by a proper amount according to a practical application and is uniformly mixed. In the PI solution to which the amphiphilic solvent is added, the amphiphilic solvent molecules are linked with the PI solution with hydrophilic moieties thereof, while hydrophobic moieties thereof are linked with organic compounds on a surface of substrate after the PI solution is coated on the substrate thereby making the PI solution uniformly spread on the substrate.

The PI solution used in the above method comprises PI molecules and a solvent. The PI molecules have hydrophobic moieties. The solvent can be N-methyl-2-pyrrolidone, γ-butyrolactone, butyl carbonate, or a mixture thereof and preferably a mixture of NMP, BC, and GBL. The PI molecules are linked with amphiphiles that have both hydrophilic moieties and hydrophobic moieties. The hydrophobic moieties of the PI molecules are the hydrophobic moieties of the amphiphiles, which are linked to the PI molecules through the hydrophilic moieties linking to the PI molecules. The amphiphiles can be any known molecule that contains both hydrophilic moieties and hydrophobic moieties of which the hydrophilic moieties can be linked with the PI molecules and the hydrophobic moieties can be linked with organic compound, especially the organic compounds existing on a surface of a substrate (such as TFT substrate or CF substrate).

Further, the PI solution comprises an amphiphilic solvent and the amphiphiles are the amphiphilic solvent molecules of the amphiphilic solvent, which have both hydrophilic moieties and hydrophobic moieties. Adding the amphiphilic solvent provides amphiphiles to link with PI molecules in the PI solution and provide hydrophobic moieties to the PI molecules for linking with organic compound existing on a substrate surface.

For a PI film formed by coating the PI solution according to the present invention to a substrate, the substrate requires no washing with cleaning agent to effect fine modification on the organic compound existing on the surface thereof, thereby saving the tedious operation of washing with cleaning agent. Or alternatively, even the subject is washed with the cleaning agent, the PI solution coating printing can be carried out in a timely manner or not in a timely manner. There is no severe restriction for the timing of operation. Even the organic compounds attached to the substrate surface are increased with time lapse, the result of PI solution coating on the substrate is not affected and the PI solution can be still uniformly spread on the substrate to provide an excellent result of coating without occurring PI non-adherence.

In summary, the present invention provides a method for improving PI non-adherence to a substrate and a PI solution. The PI solution comprises PI molecules that have hydrophobic moieties. Using the PI solution to coat on a substrate allows the hydrophobic moieties to link with organic compounds existing on a surface of the substrate to thereby enhance affinity of the PI solution to the substrate surface, improve the issue of PI non-adherence, improve the result of coating, and heighten printing quality of the substrate.

Based on the description given above, those having ordinary skills of the art may easily contemplate various changes and modifications of the technical solution and technical ideas of the present invention and all these changes and modifications are considered within the protection scope of right for the present invention.

1. A method for improving polyimide (PI) non-adherence to a substrate, comprising the following steps:
(1) providing a substrate and a PI solution, the PI solution comprising PI molecules and a solvent, the PI molecules having hydrophobic moieties; and
(2) coating the PI solution on the substrate to form a PI film.

2. The method for improving PI non-adherence to a substrate as claimed in claim 1, wherein the substrate comprises a thin-film transistor (TFT) substrate or a color filter (CF) substrate.

3. The method for improving PI non-adherence to a substrate as claimed in claim 1, wherein the solvent comprises N-methyl-2-pyrrolidone, γ-butyrolactone, butyl carbonate, or a mixture thereof.

4. The method for improving PI non-adherence to a substrate as claimed in claim 1, wherein the hydrophobic moieties are grafted on the PI molecules by polymerization reaction so as to form hydrophobic side chains of the PI molecules and in step (2), the PI molecules of the PI solution are linked to organic compounds on the substrate through the hydrophobic side chains thereof.

5. The method for improving PI non-adherence to a substrate as claimed in claim 4, wherein the hydrophobic moieties comprise alkane moieties.

6. The method for improving PI non-adherence to a substrate as claimed in claim 1, wherein the PI molecules are linked with amphiphiles that have both hydrophilic moieties and hydrophobic moieties, the hydrophobic moieties of the PI molecules are the hydrophobic moieties of the amphiphiles, which are linked to the PI molecules through the hydrophilic moieties linking to the PI molecules; in step (2), the PI molecules of PI solution are linked to organic compounds on the substrate through the hydrophobic moieties thereof.

7. A method for improving polyimide (PI) non-adherence to a substrate, comprising the following steps:
(1) providing a substrate and a PI solution, the PI solution comprising PI molecules and a solvent, the PI molecules having hydrophobic moieties; and
(2) coating the PI solution on the substrate to form a PI film;
wherein the substrate comprises a thin-film transistor (TFT) substrate or a color filter (CF) substrate;
wherein the solvent comprises N-methyl-2-pyrrolidone, γ-butyrolactone, butyl carbonate, or a mixture thereof;
wherein the hydrophobic moieties are grafted on the PI molecules by polymerization reaction so as to form hydrophobic side chains of the PI molecules and in step (2), the PI molecules of the PI solution are linked to organic compounds on the substrate through the hydrophobic side chains thereof; and
wherein the hydrophobic moieties comprise alkane moieties.

8. A polyimide (PI) solution, which comprises PI molecules and a solvent, the PI molecules being linked with molecules having hydrophobic moieties and hydrophilic moieties in such a way that the hydrophilic moieties are linked with the PI molecules to graft the hydrophobic moieties to the PI molecules, the solvent comprising N-methyl-2-pyrrolidone, γ-butyrolactone, butyl carbonate, or a mixture thereof in which the hydrophobic moieties grafted PI molecules dissolve.

9. The PI solution as claimed in claim 8, wherein the hydrophobic moieties are grafted on the PI molecules by polymerization reaction so as to form hydrophobic side chains of the PI molecules.

10. The PI solution as claimed in claim 9, wherein the hydrophobic moieties comprise alkane moieties.

11. (canceled)
